(19) United States
(12) Patent Application Publication
(10) Pub. No.: US 2025/0238290 A1
(43) Pub. Date: Jul. 24, 2025

(54) PROBABILISTIC AUTONOMOUS DATA ACQUISITION USING STOCHASTIC MTJ BASED P-BITS

(71) Applicant: KING FAHD UNIVERSITY OF PETROLEUM AND MINERALS, Dhahran (SA)

(72) Inventors: Feras Mohamad Ameer AL-DIRINI, Dhahran (SA); Saleh Ahmad S. BUNAIYAN, Dhahran (SA)

(73) Assignee: KING FAHD UNIVERSITY OF PETROLEUM AND MINERALS, Dhahran (SA)

(21) Appl. No.: 18/417,677

(22) Filed: Jan. 19, 2024

(51) Int. Cl. G06F 9/54; H03K 17/18

(52) U.S. Cl. CPC G06F 9/542; H03K 17/18

(57) ABSTRACT

A system and method for acquiring data in a probabilistic manner in an event-based data acquisition system is disclosed. The system includes a sensor from which an analog sensor signal is obtained. A feature extraction unit is configured to extract features from the analog sensor signal. The features are indicative of a presence or an absence of an event of interest. The system includes an activation unit comprising a magnetic tunnel junction (MTJ)-based p-bit, configured to generate, based on the features, an output signal for use in triggering acquisition of event data from the analog sensor signal in a probabilistic manner. P-bit is configured with a first value and a second value to decide whether to acquire the event data or not. Amount of time of data acquisition is also configured. The output of p-bit is used to activate the sampling unit, which will in-turn-upon activation-acquires the sensor output signal.

### STATEMENT OF PRIOR DISCLOSURE BY AN INVENTOR

Aspects of the present disclosure are described in “Probabilistic Autonomous Artificial Reflex Arc System” presented at the 69th Annual IEEE International Electron Devices Meeting which is incorporated herein by reference in its entirety.

### STATEMENT OF ACKNOWLEDGEMENT

The inventors acknowledge the financial support provided by the Interdisciplinary Research Center (IRC) for Advanced Materials, King Fahd University of Petroleum & Minerals (KFUPM), Riyadh, Saudi Arabia through Project No. INAM2306.

### BACKGROUND

### Technical Field

The present disclosure is directed to Sensing and Data-Acquisition Systems, more particularly, to a system and method for probabilistic autonomous data acquisition.

### Description of Related Art

The “background” description provided herein is for the purpose of generally presenting the context of the disclosure. Work of the presently named inventors, to the extent it is described in this background section, as well as aspects of the description which may not otherwise qualify as prior art at the time of filing, are neither expressly or impliedly admitted as prior art against the present invention.

The field of information processing has undergone tremendous advances in terms of intelligence and energy efficiency. These developments have enabled an ever-increasing volume of data to be processed continuously. Despite such advancements, the proliferation of data generated by sensors and Internet of Things (IoT) devices is surpassing the processing capabilities of contemporary computing and artificial intelligence systems. The primary challenge lies in the requirement of tremendous energy resources for processing the massive influx of data, which is becoming increasingly unsustainable. To overcome the challenge, the data processing solutions have to be equipped with means for effective sensory data processing as well as effective data generation and data acquisition.

Conventionally, adaptive sampling techniques have been employed to manage the flow of sensor data. The conventional techniques adjust the data sampling rates in accordance with the frequency of the incoming sensor signals. Although adaptive sampling assumes a continuous acquisition of informative data, it may not be as effective solution for IoT devices and remote sensors, which may not have such constant data flow.

Recent innovations have focused on selectivity in data collection, specifically through event-based sensing. This technique involves the selective sampling of data upon the detection of an event of interest, which is identified in real-time and often within the analog domain. Once an event is detected, specific features or the entire signal of the event may be selectively sampled. However, such a technique introduces a critical and irreversible decision-making process. Decisions reflect whether to sample or not to sample the specific information or data set. While this decision is seemingly binary, the distinction between a true event and a false event is not always clear-cut. Often, it is more appropriate to describe the decision-making process in terms of probabilistic confidence, as the onset of a true event is frequently indistinguishable from a false one. However, encapsulating this probabilistic information within the sensor data poses a significant challenge, especially when relying on deterministic digital encoding methods.

Each of the aforementioned techniques suffers from one or more drawbacks hindering their adoption. For example, the existing technologies disclose data generation but do not relate to enhancement in the intelligence of sensory data processing and to the acquisition of sensor data.

Accordingly, it is one object of the present disclosure to provide methods and systems for enhancing the intelligence of sensory data processing and acquisition of sensor data.

### SUMMARY

In an exemplary embodiment, a method for acquiring data in a probabilistic manner in an event-based data acquisition system includes obtaining an analog sensor signal from a sensor and extracting features from the analog sensor signal using a feature extraction unit. The features are indicative of a presence or an absence of an event of interest. The method further includes generating, by an activation unit, based on the features, an output signal for use in triggering acquisition of event data from the analog sensor signal in a probabilistic manner. The activation unit includes a magnetic tunnel junction (MTJ)-based p-bit.

The method step of generating the output signal includes configuring the p-bit to a first value for a period of time the features indicate a presence of the event of interest to cause acquisition of the event data, configuring the p-bit to a second value for a period of time the features indicate an absence of the event of interest to prevent acquisition of the event data, configuring an amount of time the p-bit is configured to the first value to cause acquisition of the event data randomly in a period of time wherein the features are not definitive enough to indicate an absence or a presence of the event of interest, and outputting the output signal with a value of the p-bit.

The method further includes acquiring, by a sampling unit, the event data based on the output signal.

In one aspect of the embodiment, acquiring the event data based on the output signal includes acquiring the event data from the analog sensor signal for the period of time the output signal has the first value.

In one aspect of the embodiment acquiring the event data based on the output signal includes adjusting average random data acquisition rate to a specified rate for a period of time when the features indicate an absence of the event of interest.

In one aspect of the embodiment, adjusting the average random data acquisition rate includes configuring the p-bit to the first value for a portion of the period of time when the features indicate an absence of the event of interest.

In one aspect of the embodiment, the average random data acquisition rate is adjusted by adjusting a voltage applied to a gate of a transistor of the activation unit to which the MTJ is connected.

In one aspect of the embodiment, adjusting the voltage includes increasing the voltage to increase the average random data acquisition rate.

In one aspect, acquiring the event data based on the output signal includes adjusting average random data acquisition rate to a first rate that is between a second rate and a third rate for a period of time when the features are not definitive enough to indicate an absence or presence of the event of interest. The second rate is the average random data acquisition rate corresponding to a period of time when the features indicate a presence of the event of interest and the third rate is the average random data acquisition rate corresponding to a period of time when the features indicate an absence of the event of interest.

In one aspect of the embodiment, generating the output signal includes providing an output voltage from the feature extraction unit as a first input voltage to a comparator of the activation unit. The output voltage is indicative of the features. The generating the output signal further includes providing a voltage from a drain of a transistor to which the MTJ is connected as a second input voltage to the comparator. The comparator determines a value of the p-bit based on the first input voltage and the second input voltage.

In one aspect of the embodiment, the method further includes performing a logical AND operation between the output signal and a synchronous clock signal to generate an output clock signal.

In one aspect of the embodiment, acquiring the event data includes acquiring the event data based on the output clock signal.

In another exemplary embodiment, a method for acquiring data in a probabilistic manner in an event-based data acquisition system includes extracting, using a feature extraction unit, features from an analog sensor signal. The features are indicative of a presence or an absence of an event of interest. The method further includes generating, by an activation unit comprising a magnetic tunnel junction (MTJ)-based p-bit, an output signal indicative of an output of the p-bit based on the features. The output includes a first value or a second value of the p-bit for different periods of time. The first value is indicative of a presence of the event of interest in the features and the second value is indicative of an absence of the event of interest in the features. The method further includes acquiring, by a sampling unit, the event data from the analog sensor signal for the period of time the output signal has the first value.

In yet another exemplary embodiment, an event-based data acquisition system for acquiring data in a probabilistic manner includes a feature extraction unit, an activation unit, and a sampling unit.

The feature extraction unit is configured to extract features from an analog sensor signal. The features are indicative of a presence or an absence of an event of interest in the analog sensor signal.

The activation unit includes a magnetic tunnel junction (MTJ)-based p-bit. The activation unit is configured to generate an output signal based on the features. The output signal is indicative of an output of the p-bit, the output including a first value or a second value of the p-bit for different periods of time. The first value is indicative of a presence of the event of interest in the features and the second value is indicative of an absence of the event of interest in the features.

The sampling unit is configured to acquire the event data from the analog sensor signal for the period of time the output signal has the first value.

The foregoing general description of the illustrative embodiments and the following detailed description thereof are merely exemplary aspects of the teachings of this disclosure, and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1A shows a schematic illustrating the spinal reflex arc response of the Autonomous Nervous System (ANS) to external stimuli, according to certain embodiments.

FIG. 1B illustrates a system architecture for probabilistic autonomous data acquisition, according to certain embodiments.

FIG. 2A illustrates a functional diagram of an event-based data acquisition system based on a feature extraction, according to certain embodiments.

FIG. 2B illustrates a functional diagram of a probabilistic autonomous sensing system, based on a probabilistic autonomous data-acquisition, according to certain embodiments.

FIG. 3A illustrates exemplary emulation of magnet fluctuation dynamics for a circular in-plane magnetic anisotropy (IMA) magnet, according to certain embodiments.

FIG. 3B illustrates exemplary emulations of magnet fluctuation dynamics for an isotropic magnet, according to certain embodiments.

FIG. 3C illustrates exemplary emulations of magnet fluctuation dynamics for an IMA low barrier magnet (LBM), according to certain embodiments.

FIG. 3D illustrates exemplary emulations of magnet fluctuation dynamics for a perpendicular magnetic anisotropy (PMA) LBM, according to certain embodiments.

FIG. 4A is a graphical representation of probabilistic autonomous sensing, according to certain embodiments.

FIG. 4B is a graphical representation of activation of sampling based on binary event detection (BED) and probabilistic event detection (PED), when X is set to zero, according to certain embodiments.

FIG. 4C is a graphical representation of activation of sampling based on binary event detection (BED) and probabilistic event detection (PED), when X is set to be greater than zero, according to certain embodiments.

FIG. 5A depicts a functional diagram of a Magnetic tunnel junction (MTJ), according to certain embodiments.

FIG. 5B depicts a graphical representation of Sample transient stochastic MTJ magnetization m_{z}(t) fluctuation dynamics, according to certain embodiments.

FIG. 5C depicts a graphical representation of the probability distribution of m_{z}(t) showing uniform m_{z}(t) distribution, according to certain embodiments.

FIG. 5D-FIG. 5E illustrates a system block diagram of a probabilistic autonomous sensing system employing a probabilistic-bit (p-bit), according to certain embodiments.

FIG. 6A illustrates a circuit diagram of a probabilistic autonomous sensing system employing a probabilistic-bit (p-bit) in a digital implementation, according to certain embodiments.

FIG. 6B is a graphical representation of the response of the probabilistic activation unit, according to certain embodiments.

FIG. 7A illustrates a block diagram of the architecture of the probabilistic autonomous data acquisition system, according to certain embodiments.

FIG. 7B illustrates a component-level circuit design used for the implementation of the probabilistic autonomous data acquisition system, according to certain embodiments.

FIG. 8A shows simulation results of probabilistic event detection during an active seismic event using the proposed probabilistic autonomous data acquisition system, where V_{REF}=−0.5 V, according to certain embodiments.

FIG. 8B shows simulation results of probabilistic event detection during an active seismic event using the proposed probabilistic autonomous data acquisition system, where V_{REF}=−0.3 V, according to certain embodiments.

FIG. 9A illustrates transient plots of the reconstructed sensor signals for seismic activity 1, according to certain embodiments.

FIG. 9B illustrates corresponding frequency spectra for the sensor signals for seismic activity 1, according to certain embodiments.

FIG. 9C illustrates transient plots of the reconstructed sensor signals for seismic activity 2, according to certain embodiments.

FIG. 9D illustrates corresponding frequency spectra for the sensor signals for seismic activity 2, according to certain embodiments.

FIG. 9E illustrates transient plots of the reconstructed sensor signals for seismic activity 3, according to certain embodiments.

FIG. 9F illustrates corresponding frequency spectra for the sensor signals for seismic activity 3, according to certain embodiments.

FIG. 9G illustrates transient plots of the reconstructed sensor signals for seismic activity 4, according to certain embodiments.

FIG. 9H illustrates corresponding frequency spectra for the sensor signals for seismic activity 4, according to certain embodiments.

### DETAILED DESCRIPTION

In the drawings, like reference numerals designate identical or corresponding parts throughout the several views. Further, as used herein, the words “a”, “an” and the like generally carry a meaning of “one or more”, unless stated otherwise.

Furthermore, the terms “approximately,” “approximate”, “about” and similar terms generally refer to ranges that include the identified value within a margin of 20%, 10%, or preferably 5%, and any values therebetween.

Aspect of this disclosure are directed to acquisition of data in a probabilistic manner in an event-based data acquisition system by extracting features from analog sensor signal, and based on the features, generating an output signal for use in triggering acquisition of the event data. The output signal is generated using a Magnetic Tunnel Junction (MTJ) based P-bit.

In the field of computational technology, a new paradigm known as probabilistic computing is being implemented for various applications. The probabilistic computing facilitates the integration of probabilistic information within the operational dynamics of a digital bit, termed a probabilistic bit or p-bit. A p-bit retains the fundamental binary information by representing data as either ‘1’ or ‘0’. Distinctively, it introduces the capability to randomly oscillate between the binary states in a probabilistically controlled manner. This random oscillatory fluctuation is not arbitrary; it is adjustable and deliberately orchestrated, enabling the p-bit to encode a layer of probabilistic information through its time-domain dynamics. The tunable stochastic behaviour of the p-bit provides a mechanism to capture and express probabilistic nuances within binary computing frameworks. This duality of deterministic and probabilistic functionalities within a single bit paves the way for enhanced computational processes, particularly in scenarios where decision-making involves elements of uncertainty and risk.

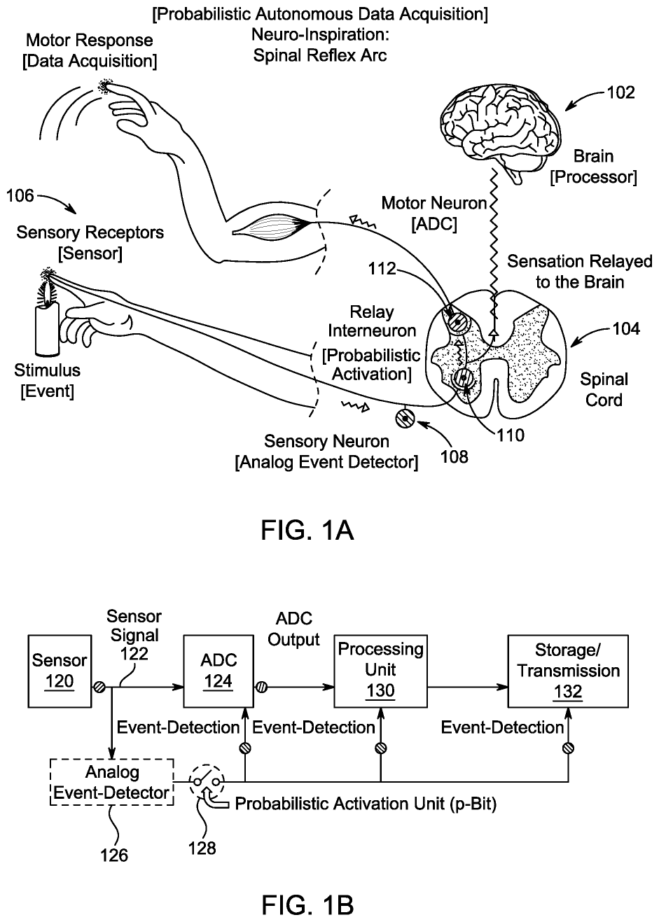

FIG. 1A shows a schematic illustrating the spinal reflex arc response of the Autonomous Nervous System (ANS) to external stimuli, in accordance with the present embodiment. In one aspect, a p-bit is employed in an event-based data acquisition system in order to achieve probabilistic autonomous sensing. FIG. 1A particularly shows the physiological response of a human body when a human finger comes into contact with a source of heat, such as fire, leading to a burn, and the subsequent neural reaction.

When a human finger touches a flame, the skin's sensory receptors 106, in this example, thermal receptors, immediately detect the excessive heat. Sensory neurons 108 in the finger are activated by this painful stimulus and generate an electrical signal. This signal travels along the sensory neurons' 108 axons towards the spinal cord 104, a process known as the afferent pathway.

Upon reaching the spinal cord 104, the signal enters through the dorsal horn and is transmitted to interneurons 110. The interneurons 110 serve as a relay, processing the incoming information. The interneurons 110 play a crucial role in reflex arcs, where a rapid response is needed. In the present example, the interneurons 110 quickly send signals to motor neurons 112 within the spinal cord 104 without involving the brain 102 in the initial decision, facilitating an immediate response.

The motor neurons 112, receiving the urgent signal, project their axons out of the spinal cord 104 through the ventral horn and towards the muscles in the hand. This signal from the motor neurons 112 causes the muscles to contract, effectively pulling the hand away from the flame.

Simultaneously, the sensory signal is relayed to the brain 102, reaching the thalamus and then the cerebral cortex, where the sensation of pain is registered, and the conscious realization of the burn occurs. However, this recognition in the brain comes after the reflex action has already initiated the withdrawal of the hand, demonstrating the body's rapid protective response to injury.

Such orchestrated response involving sensory neurons, interneurons, and motor neurons allows for both an immediate reflexive withdrawal from the heat source to minimize tissue damage and a delayed conscious reaction to the painful stimulus.

FIG. 1B illustrates a system architecture for probabilistic autonomous data acquisition, in accordance with the present embodiment. As described with reference to FIG. 1A, when a human finger comes into contact with a high-temperature source like a flame, the event can be likened to a sensor 120, such as the skin and thermal receptors, detecting a critical environmental change, such as the excessive heat. In such events, how the human body detects the event can be viewed as the event detection, and in response, how the muscles receive sensory feedback from the neurons resulting in retracting the hand from the heat source can be viewed as sensory data generation and acquisition. Such physiological system can be replicated with electronic components to mimic the neuro-inspired system for an event-based data acquisition system.

Referring back to FIG. 1B, in an event-based data acquisition system, the sensor 120 is configured to collect sensory data. In various implementations, a multiplicity of sensors can be implemented to sense specific type of events. For example, thermal sensors to sense the heat. The thermal receptors in the skin act as the sensors. Upon detecting the thermal energy from the flame, the sensors generate an electrical signal. Such generation of the electrical signal is analogous to a transducer in a sensor system.

The electrical signal generated by the sensor 120 is then transmitted to an Analog-to-Digital Converter (ADC) 124 for converting the analogue signal into the digital signal. In physiological system, the electrical signal is transmitted to the spinal cord, functioning similarly to an ADC 124. In biological terms, conversion would involve the conversion of the analog pain signal into a form that can be processed by the nervous system. An ADC output is the digital signal corresponding to the sensor signal.

A processing unit 130 then processes the ADC output. The processing unit 130 is capable of handling various tasks, including signal decoding, event detection and prioritization, real-time processing of signals. Execution of pre-programmed responses, feedback loop management, parallel processing, interruption handling, and the like. In the example illustrated in FIG. 1A, when the electrical signal reaches the spinal cord 104, interneurons 110 function as the processing unit 130. The interneurons receive the digitized signal and determine the appropriate response. At the spinal cord 104, the signal can be processed for both reflex actions and conscious perception. For conscious perception, the brain 102 acts as the processing unit 130, whereas for the reflex, the interneurons at the spinal cord 104 function as the processing unit 130.

The event-based data acquisition system further includes a storage and transmission system 132 configured to store the event related data and manage the transmission of the stored data. For storing the collected data, the storage and transmission system 132 is implemented by various means, including memory cards, hard drives, or cloud storage. The storage and transmission system 132 can be both, temporary and permanent storage solutions.

In one aspect, the event-based data acquisition system further includes an analog event detector. The Analog event detector 126 is configured for event detection process, parallel to the ADC 124 process. Each signal collected by the sensor 120 is analyzed to detect an event. The event can be an interrupt signal created in response to an unusual activity, for example, a burn on the skin. The event detection can be compared to the initial detection of the burn by the sensory neurons before the signal is fully processed by the spinal cord 104.

At each step of the event-based data acquisition, event detection signal is provided through a Probabilistic Activation Unit 128, also referred as to 128. The P-bit 128 is used in the field of probabilistic computing, which is a paradigm that differs from traditional deterministic computing. In a standard binary computing system, a bit is the basic unit of information and can exist in one of two definite states: 0 or 1. However, in probabilistic computing, a p-bit is designed to represent a binary state that is not fixed; instead, it fluctuates between 0 and 1 with certain probabilities. In one aspect, the p-bit 128 has a certain probability of being in the state ‘0’ and a certain probability of being in the state ‘1’. For example, the p-bit 128 can be in state of ‘0’ during normal signals, and upon detection of event or interruption signal, the p-bit 128 can switch the state to ‘1’. In the example of burn on the skin, the p-bit 128 decides whether the event requires a reflex action, based on the likelihood of tissue damage. Based on the decision, corresponding event detection signal is sent to the ADC 124, the processing unit 130, and the storage and transmission system 132. The p-bit 128 introduces a level of decision-making that determines the response's intensity.

In short, in the system illustrated by FIG. 1B in conjunction with FIG. 1A, the ‘sensor’ 120 (thermal receptors) detects an ‘event’ (the burn), which triggers the ‘ADC’ (sensory neurons) 124 to send a signal to the ‘processing unit’ (spinal cord and interneurons) 130. The ‘processing unit’ 130 then relays a command to the ‘actuator’ (muscles) to withdraw the finger. Concurrently, the ‘event detection’ happens at multiple levels to assess the situation and adjust the response as needed, guided by a probabilistic activation unit 128 that adds a layer of decision-making based on the probability of actual harm.

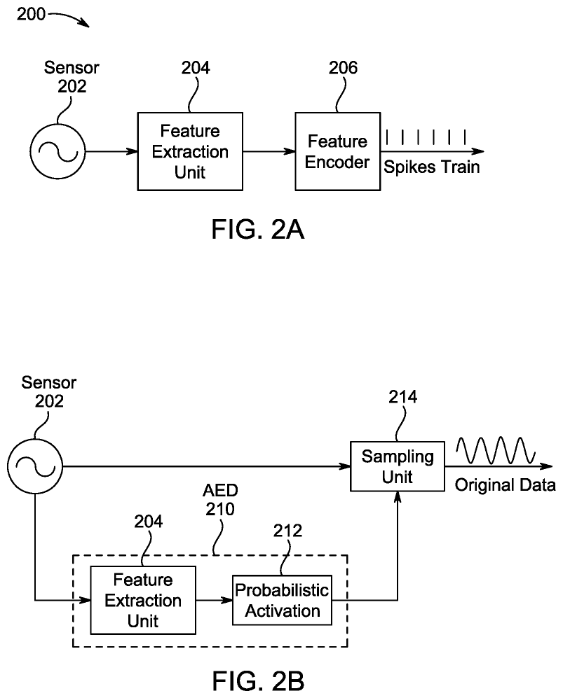

FIG. 2A illustrates a functional diagram of an event-based data acquisition system 200 based on a feature extraction, in accordance with the present embodiment. The event-based data acquisition system 200, also referred as to the system 200 hereinafter, includes a sensor 202, a feature extraction unit 204, and a feature encoder 206.

The feature extraction unit 204 performs a feature extraction process. The feature extraction is the process of transforming raw analog sensor signals into a set of measurable, quantifiable, and informative characteristics, known as features. These features are derived from the raw data to capture essential information about the event being sensed. For example, in the case of a thermal sensor detecting heat, feature extraction would involve identifying relevant data points that indicate a rise in temperature, the rate of temperature change, or the duration of the exposure to heat.

After the features have been extracted, the features have to be represented in a format that can be processed by the subsequent stages of the system 200. The features are fed to the feature encoder 206 to perform feature encoding process. Feature encoding is the process of converting these extracted features into a format that can be processed by the processing unit (not shown in the figure) of the system 200, as such to detect the event occurrence.

FIG. 2B illustrates a functional diagram of an event-based data acquisition system 200, based on a probabilistic autonomous data-acquisition, in accordance with the present embodiment. This system includes an Analogue Event Detector (AED) 210 and a sampling Unit 214, alternatively referred as to a data acquisition unit 214. The sensory data detected by the sensor 202 is fed to the AED 210. The AED 210 includes the feature extraction unit 204 and an activation unit (p-bit) 212, alternatively referred as to a probabilistic activation unit 212. The sensory signal from the sensor 202 is received by the feature extraction unit 204. The feature extraction unit 204 is configured to extract features from an analog sensor signal. The features are indicative of a presence or an absence of an event of interest in the analog sensor signal.

Features extracted by the feature extraction unit 204 are then fed to the activation unit 212. The activation unit 212 functions as a trigger mechanism. Depending on the presence of a distinct event, the activation unit 212 either initiates the process of data gathering or maintains the other components of the system in sleep/idle mode. The activation unit 212 includes a magnetic tunnel junction (MTJ)-based p-bit. The activation unit 212 is configured to generate an output signal based on the features. The output signal is indicative of an output of the p-bit, the output includes a first value (i.e., ‘1’) or a second value (i.e., ‘0’) of the p-bit for different periods of time. The first value is indicative of a presence of the event of interest in the features and the second value is indicative of an absence of the event of interest in the features. P-bit state and indication parameters are configurable, in another embodiment. For example, the first value can be ‘0’ and the second value can be ‘1’.

In one aspect, the activation unit 212 is further configured to receive an output voltage from the feature extraction unit 204 as a first input voltage. The output voltage is indicative of the features. The activation unit 212 is further configured to determine a value of the p-bit based on the first input voltage and a second input voltage at a drain of a transistor to which the MTJ is connected. The activation unit 212 can adjust average random data acquisition rate of the sampling unit for a period of time when the features indicate an absence of the event of interest based on a voltage applied to a gate of a transistor to which the MTJ is connected.

The sampling unit 214 is configured to acquire the event data from the analog sensor signal for the period of time the output signal has the first value. The sampling unit 214 acts after the initial stages of sensing and processing have determined that an event worth capturing has occurred.

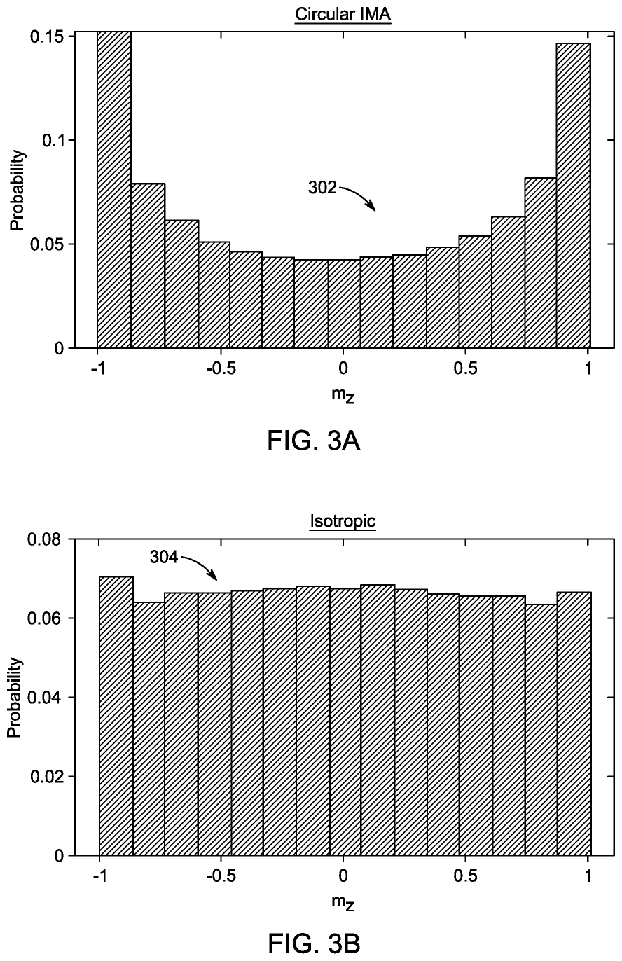

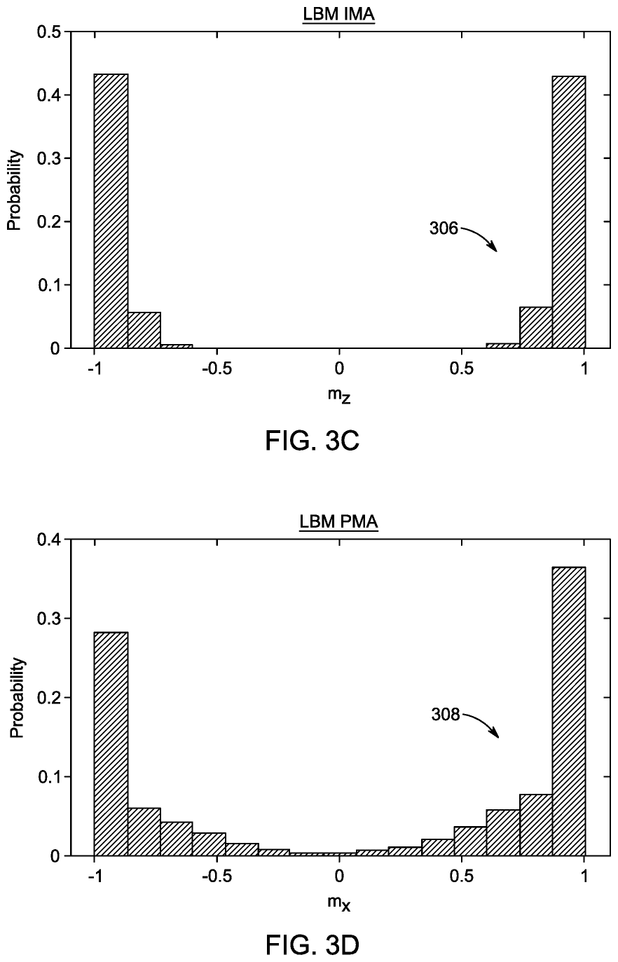

FIG. 3A illustrates a sample emulations of magnet fluctuation dynamics for a circular in-plane magnetic anisotropy (IMA) magnet, in accordance with the present embodiment. Curve 302 indicates the probability distribution of dynamic magnetization state (m_{z}(t)) of the stochastic magnetic tunnel junction (sMTJ) for IMA magnet.

FIG. 3B illustrates a sample emulations of magnet fluctuation dynamics for an isotropic magnet, in accordance with the present embodiment. Curve 304 indicates the probability distribution of dynamic magnetization state (m_{z}(t)) of the stochastic magnetic tunnel junction (sMTJ) for the isotropic magnet.

FIG. 3C illustrates a sample emulations of magnet fluctuation dynamics for an IMA low barrier magnet (LBM), in accordance with the present embodiment. Curve 306 indicates the probability distribution of dynamic magnetization state (m_{z}(t)) of the stochastic magnetic tunnel junction (sMTJ) for the LBM IMA magnet.

FIG. 3D illustrates a sample emulations of magnet fluctuation dynamics for a perpendicular magnetic anisotropy (PMA) LBM, in accordance with the present embodiment. Curve 308 indicates the probability distribution of dynamic magnetization state (m_{z}(t)) of the stochastic magnetic tunnel junction (sMTJ) for LBM PMA.

FIG. 3A-FIG. 3D illustrates probability distribution of magnetization. The event-based data acquisition system, based on a probabilistic autonomous data-acquisition, employing a p-bit as the activation unit 212 was designed and simulated using LTSPICE software. The SPICE simulation environment was coupled with MATLAB in order to simulate the stochastic p-bit dynamics, which were controlled by the magnetization state (m_{z}(t)) of the stochastic magnetic tunnel junction (sMTJ), whose conductance (G(t)) is defined as:

$$G ( t ) = {G}_{0} [ 1 + {m}_{z} ( t ) \frac{T M R}{2 + T M R} ] \qquad ( 1 )$$

where G₀ is the average conductance and TMR is the tunneling magnetoresistance ratio, which depends on the ratio between the parallel (R_{P}) and the anti-parallel (R_{AP}) resistance states of the sMTJ and is defined as: TMR=(R_{AP}−R_{P})/R_{P}.

MATLAB was used to emulate the sMTJ's dynamic magnetization state m_{z}(t) and its probability distribution as shown in FIG. 3A-FIG. 3D. The resultant m_{z}(t) vector was then used in solving equation (1) to obtain a time varying G(t) vector. SPICE then receives the sMTJ's response as a time-varying resistance according to G(t).

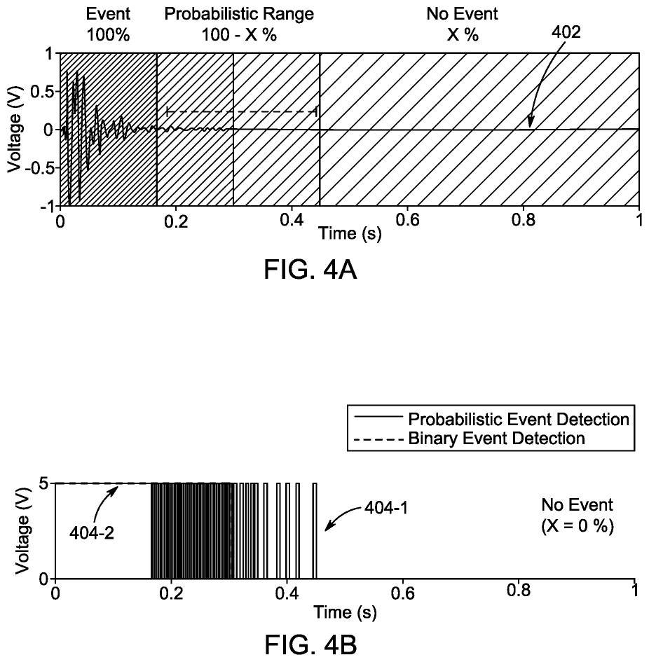

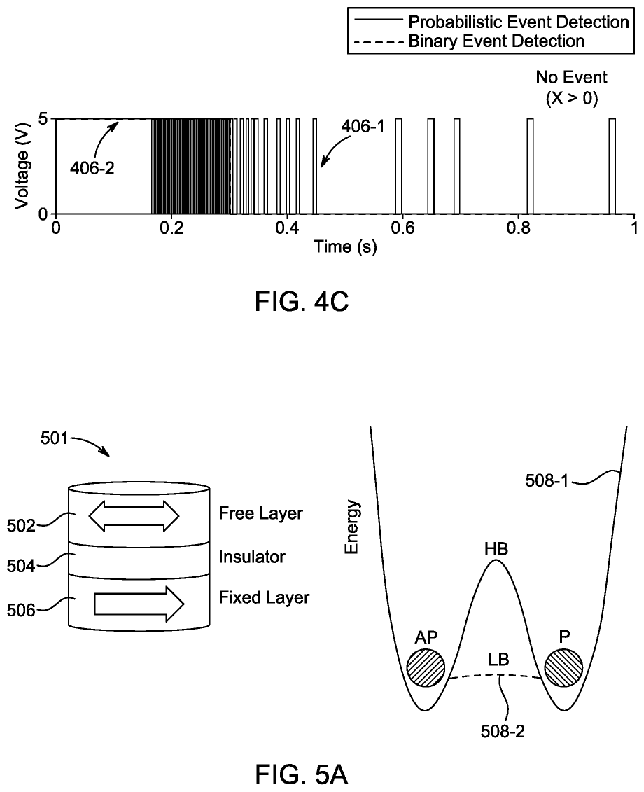

FIG. 4A is a graphical representation of probabilistic autonomous sensing, in accordance with the present embodiment. In an example, a sensor signal is received from a seismic geophone signal illustrating regions that are definitive events (event 100%), definitive ‘no events’ (no-event 100%), and the probabilistic range in-between (100-X %). Output signal is shown by curve 402. If the event features are not prominent enough to declare a definite event, the p-bit would activate probabilistic random sampling instead as depicted by the probabilistic range.

FIG. 4B is a graphical representation of activation of sampling based on binary event detection (BED) and probabilistic event detection (PED), when the minimum average no-event random sampling rate, X, is set to zero. Curve 404-1 depicts PED, and curve 404-2 depicts BED. As illustrated, no events are sampled during the definitive no-events period. However, the minimum average no-event random sampling rate X in PED can be tuned during periods of definitive no-events, as illustrated in FIG. 4C.

FIG. 4C is a graphical representation of activation of sampling based on binary event detection (BED) and probabilistic event detection (PED), when X is set to be greater than zero. Curve 406-1 depicts probabilistic event detection (PED), and curve 406-2 depicts BED. During periods of definitive no-events, the minimum average no-event random sampling rate X in PED can be tuned.

The degree of confidence in the detection of the onset of an event (i.e., the probability that a true event has been detected) is encoded into the time domain by controlling the average percentage of time the p-bit produces a ‘1’ output, or in other words, the average percentage of time that data would be randomly sampled.

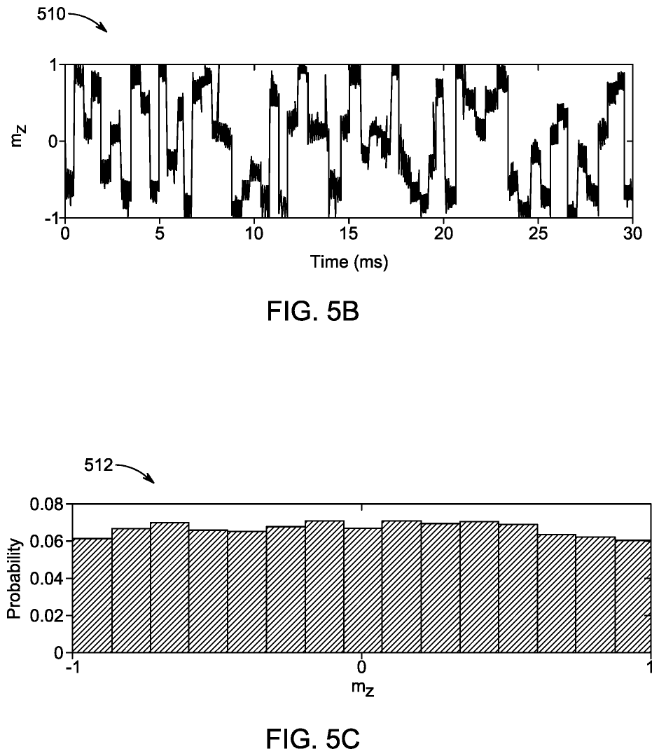

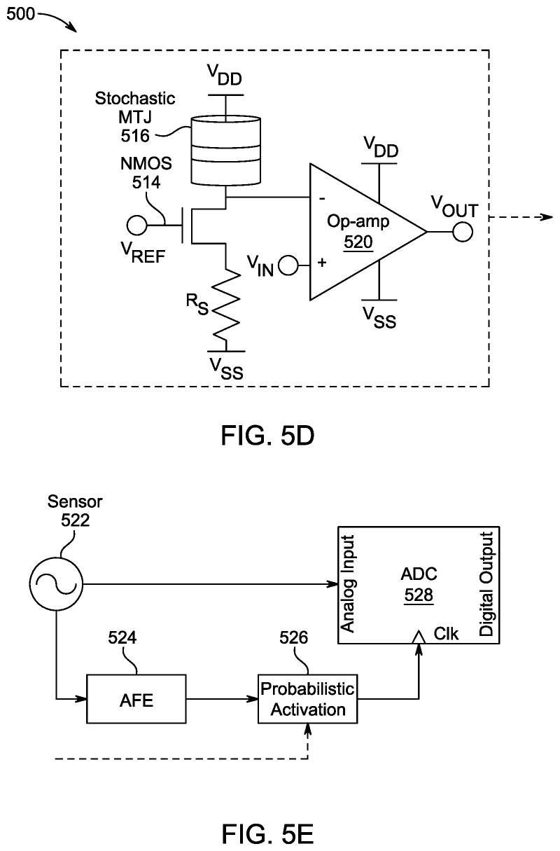

FIG. 5A depicts a functional diagram of a Magnetic tunnel junction (MTJ), in accordance with the present embodiment. The MTJ 501 consists of a free layer 502 and a fixed layer 506 with an insulator layer 504 in-between. High barrier (HB) magnets 508-1 are deterministic while low barrier (LB) magnets 508-2 are stochastic. The left side of the energy curve represents the anti-parallel (AP) state while the right side represents the parallel (P) state. The energy curve illustrates that at high barrier more energy is needed to move from AP to P or vice versa, while for low barrier much less energy is needed (e.g., thermal noise).

FIG. 5B depicts a graphical representation of Sample transient stochastic MTJ magnetization m_{z}(t) fluctuation dynamics, in accordance with the present embodiment. The m_{z}(t) was emulated with MATLAB with a retention time (τ)˜500 us and is depicted by curve 510. FIG. 5C depicts a graphical representation of the probability distribution of m_{z}(t) showing uniform m_{z}(t) distribution, in accordance with the present embodiment. m_{z}(t) represents characteristic of isotropic MTJs. The distribution is depicted by curve 512.

FIG. 5D-FIG. 5E illustrates a system block diagram of a probabilistic autonomous sensing system 500 employing a probabilistic-bit (p-bit), in accordance with the present embodiment. The probabilistic autonomous sensing system, also referred as to a system 500, includes a n-type metal-oxide-semiconductor (NMOS) 514, a stochastic MTJ 516, and an operational amplifier 520. The NMOS 514 transistor acts as a very low resistance between the output and the negative supply when its input is high and is configured as an amplifier for detection application. The NMOS 514 is coupled to the stochastic MTJ 516 which is implemented as p-bits. The stochastic MTJ 516 can switch between its two magnetic states in a way that is stochastic, making it a physical realization of a p-bit. Output signal of the p-bit is provided to the operational amplifier 520 for voltage amplification. Amplified voltage is then provided as an output. In some embodiments, an activation unit 526, alternatively referred to as the probabilistic activation unit, 526 may be implemented using the system 500, or in other words, the system 500 is an example implementation of the activation unit 126. The activation unit 526 also receives the signal from an Analog Feature Extraction (AFE) 524, which is provided as input (VIN) to the operational amplifier 520 of the system 500. The AFE 524 extracts features directly from the analog sensor signal collected by a sensor 522, and then uses the extracted features to drive the input of the p-bit (activation unit 526). Output of the p-bit is then used to control the activation of the ADC 528.

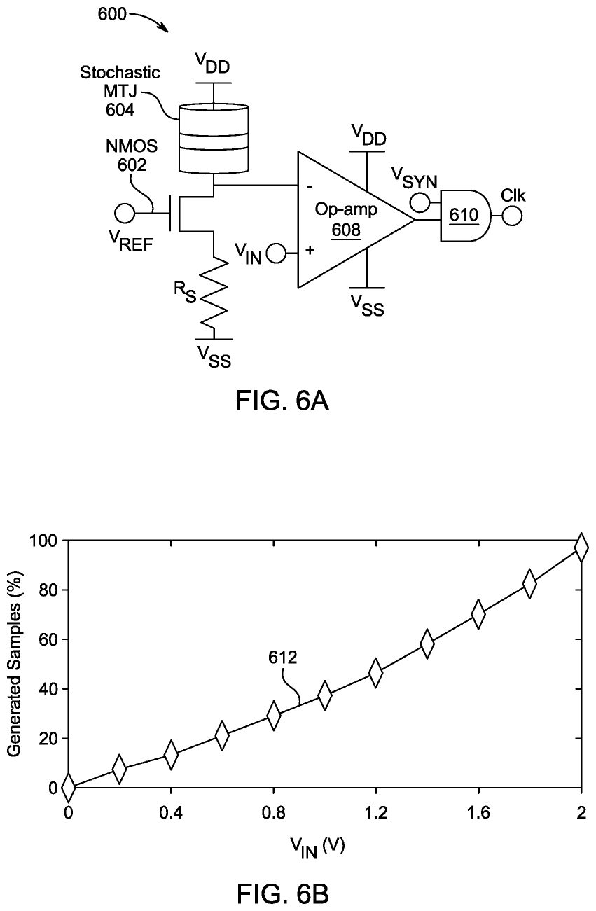

FIG. 6A illustrates a circuit diagram of a probabilistic activation unit 600 employing a probabilistic-bit (p-bit) in a digital implementation, in accordance with the present embodiment. The circuit diagram depicts the similar implementation as of FIG. 5D-FIG. 5E, except that FIG. 6A is a digital implementation of the probabilistic activation unit, also referred as to the system 600. The system 600 includes a n-type metal-oxide-semiconductor (NMOS) 602, a stochastic.

MTJ 604 as p-bit, an operational amplifier 608, and an AND gate to produce binary output signal. In one aspect, the p-bit 604 is ANDED with a synchronous clock V_{SYN} to preserve the uniformity in the acquired samples.

FIG. 6B is a graphical representation of the response of the probabilistic activation unit, in accordance with the present embodiment. The response is determined based on the presence of informative data from the sensor, evaluated over 2000 samples. The response is depicted by curve 612.

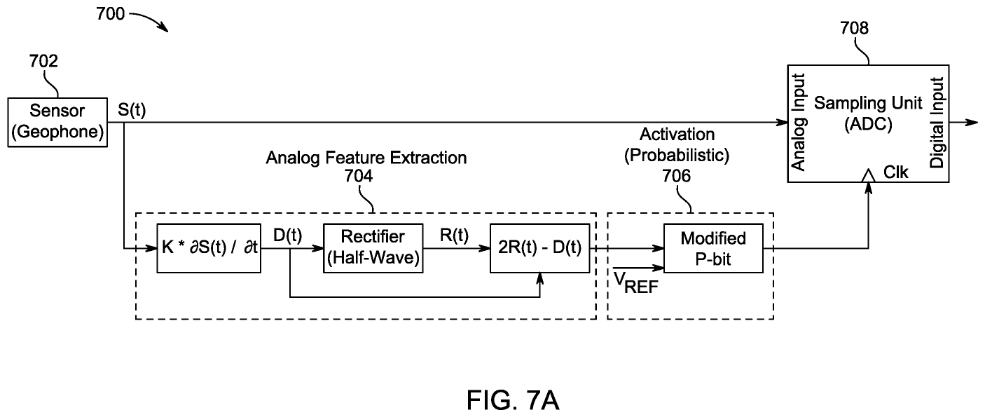

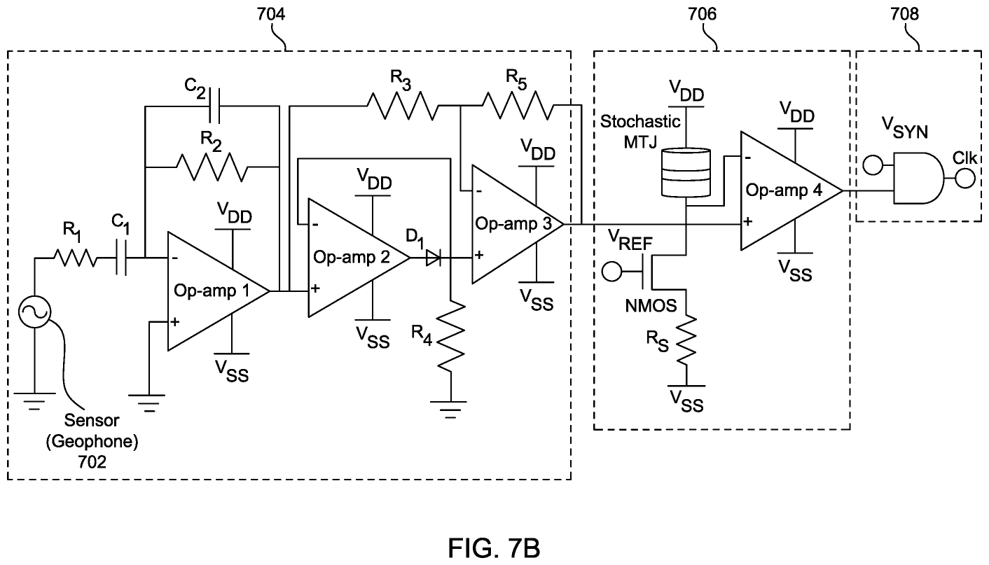

FIG. 7A illustrates a block diagram of the architecture of the probabilistic autonomous data acquisition system 700. The probabilistic autonomous data acquisition system is also referred as to the system 700. The architecture includes, but may not be limited to, an Analog Feature Extraction (AFE) unit 704, a probabilistic activation unit 706, also referred as to the activation unit, and an Analog to Digital Converter (ADC) 708, also referred as to a sampling unit. The sensor 702, for example a geophone, is configured to collect sensory data. An analog sensor signal corresponding to the sensory data is obtained from the sensor 702 and provided to the AFE unit 704. The AFE unit 704 is configured for extracting features from the analog sensor signal. The features are indicative of a presence or an absence of an event of interest. The extracted features are then utilized to stimulate the probabilistic activation unit's 706 input. The activation unit 706 includes a magnetic tunnel junction (MTJ)-based p-bit. The activation unit 706 generates an output signal for use in triggering acquisition of event data from the analog sensor signal in a probabilistic manner. For generation of the output signal, the p-bit is configured. In FIG. 7A K*dS/dt represents the differentiation of the sensor signal S(t) multiplied by some gain K. The output from the differentiator is denoted as D(t), which is supplied to a half-wave rectifier whose output is donated as R(t). Finally, the rectified feature R(t) is subtracted from D(t) according to the formula: 2D(t)−R(t), resulting in a full-wave rectification of the differentiated signal D(t). This fully rectified output is supplied as an input to the probabilistic activation unit (modified p-bit).

In one aspect of a certain embodiment, the p-bit is configured to a first value for a period of time the features indicate a presence of the event of interest to cause acquisition of the event data. Therefore, if the first value, i.e., ‘1’ is output for a period of time, (for example, 500 ms), it will be indication of a presence of the event of interests, and event data will be acquired. In one aspect, the p-bit is configured to a second value for a period of time the features indicate an absence of the event of interest to prevent acquisition of the event data. Therefore, if the first value, i.e., ‘0’ is output for a period of time, (for example, 500 ms), it will be indication of an absence of the event of interests, and the event data will be prevented from acquisition. In one aspect, an amount of time the p-bit is configured to the first value to cause acquisition of the event data randomly in a period of time, where the features are not definitive enough to indicate an absence or a presence of the event of interest. In one aspect, the output from the p-bit is used to activate the sampling unit 708, which subsequently, acquires the sensor output signal.

In an exemplary embodiment, where the output is generated and the output includes, a first value or a second value of the p-bit for different periods of time, and the first value is indicative of a presence of the event of interest in the features and the second value is indicative of an absence of the event of interest in the features, then the event data from the analog sensor signal is acquired for the period of time the output signal has the first value.

In accordance with the exemplary embodiment, an output voltage from the feature extraction unit is provided as a first input voltage to a comparator (e.g., operational amplifier) of the activation unit 706. The output voltage is indicative of the features. Further, a voltage from a drain of a transistor to which the MTJ is connected is provided as a second input voltage to the comparator. The comparator determines the output signal based on the first input voltage and the second input voltage.

Further in accordance with the exemplary embodiment, the p-bit is configured to the first value for a period of time the features indicate a presence of the event of interest to cause acquisition of the event data. The p-bit is further configured to the second value for a period of time the features indicate an absence of the event of interest to prevent acquisition of the event data. An amount of time the p-bit is configured to the first value to cause acquisition of the event data randomly in a period of time wherein the features are not definitive enough to indicate an absence or a presence of the event of interest is also configured. In some embodiments, the amount of time is configured such that a first average random data acquisition rate for a period of time when the features are not definitive enough to indicate an absence or presence of the event of interest is between a second rate and a third rate, where the second rate is the average random data acquisition rate corresponding to a period of time when the features indicate a presence of the event of interest and the third rate is the average random data acquisition rate corresponding to a period of time when the features indicate an absence of the event of interest. Then the output signal outputs a value of the p-bit.

According to the present embodiment, p-bits are utilized as Tunable True Random Number Generators (TRNGs), allowing for the adjustment of the respective stochastic response. The tunability is essential for controlling two critical parameters, first, the average probability of random sampling within the probabilistic operational range, and second, the minimal average sampling rate during periods without events (denoted as X). The first parameter is crucial for the effective implementation of probabilistic sensing, whereas the second is advantageous in applications that focus on gathering post-event information and monitoring background noise.

To achieve the required precision in adjusting the probabilistic output of the p-bit, a modified design of the p-bit is implemented in accordance with one aspect of the embodiment. The modified design allows for direct application of the input voltage (e.g., from feature extraction unit) to the comparator, while maintaining a constant gate voltage (V_{REF}). The modified p-bit is shown in FIG. 7B (e.g., also in FIGS. 5D and 6A).

Furthermore, for the purpose of ensuring compatibility and smooth integration with traditional systems, a logical AND operation is performed between the output signal and a synchronous clock signal to generate an output clock signal. The resulting output is then directed to the clock input of the ADC 708, ensuring proper synchronization and functionality within the overall system architecture.

In one aspect, acquisition of the event data based on the output signal includes, first, acquiring the event data from the analog sensor signal for the period of time the output signal has the first value. Second, adjusting average random data acquisition rate to a specified rate for a period of time when the features indicate an absence of the event of interest. Adjusting the average random data acquisition rate includes configuring the p-bit to the first value for a portion of the period of time when the features indicate an absence of the event of interest. Acquisition of the event data is performed based on the output clock signal.

In one aspect, output generation includes, first, provision of an output voltage from the AFE unit 704 as a first input voltage to a comparator of the activation unit 706. The output voltage is indicative of the features. Second, provision of a voltage from a drain of a transistor to which the MTJ is connected as a second input voltage to the comparator. The comparator determines a value of the p-bit based on the first input voltage and the second input voltage.

In one aspect, acquisition of the event data based on the output signal includes adjusting average random data acquisition rate to a first rate that is between a second rate and a third rate for a period of time when the features are not definitive enough to indicate an absence or presence of the event of interest. The second rate is the average random data acquisition rate corresponding to a period of time when the features indicate a presence of the event of interest and the third rate is the average random data acquisition rate corresponding to a period of time when the features indicate an absence of the event of interest.

In one aspect, average random data acquisition rate is adjusted to a non-zero rate for a period of time when the features indicate an absence of the event of interest. In one aspect, the average random data acquisition rate (e.g., during a definite no-event period) is adjusted by adjusting a voltage applied to a gate of a transistor of the activation unit 706 to which the MTJ is connected. The average random data acquisition rate can be adjusted by adjusting the voltage. For example, the average random data acquisition rate can be increased by increasing the voltage.

FIG. 7B illustrates a component-level circuit design used for the implementation of the probabilistic autonomous data acquisition system 700. The AFE 704, implemented in three stages, extracts features and provides the extracted features to the p-bit (of activation unit 706), described with reference to FIG. 6B. Output of the p-bit (part of activation unit 706) is then directed to the ADC 708. The AFE circuit consists of three stages: the first stage is a Differentiator circuit, encompassed by Op-amp1, R1, C1, R2, and C2; the second stage is a Precision Rectifier, encompassed by Op-amp2 and a diode (D1); the third stage is a Subtractor circuit, encompassed by Op-amp3, R3, R4, and R5.

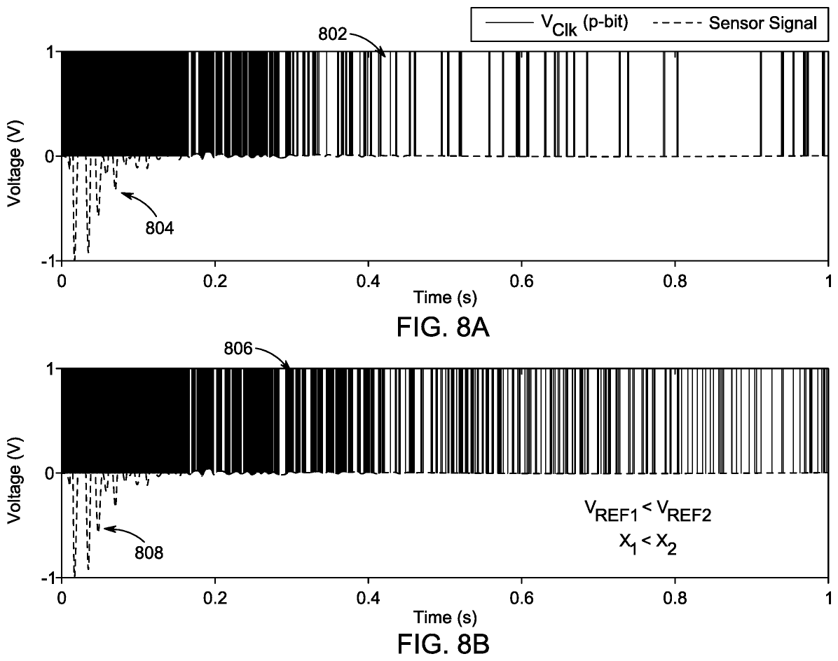

FIG. 8A shows simulation results of probabilistic event detection during an active seismic event using the proposed probabilistic autonomous data acquisition system, where V_{REF}=−0.5 V, in accordance with one embodiment. Curve 802 represent output of p-bit voltage Volk (e.g., sampling of sensory signal). Curve 804 indicates sensory signal. FIG. 8B shows simulation results of probabilistic event detection during an active seismic event using the proposed probabilistic autonomous data acquisition system, where V_{REF}=−0.3 V, in accordance with one embodiment. In one aspect, V_{REF}1<V_{REF2} and minimum average random sampling rate X1<minimum average random sampling rate X2. Curve 806 represent output of p-bit voltage V_{CLK}. Curve 808 indicates sensory signal. The gate voltage (V_{REF}) is varied to demonstrate its control over the minimum average random sampling rate (X) during no-event periods.

To evaluate the practicality and effectiveness of the system, the entire configuration depicted in FIG. 7 was constructed utilizing an NMOS transistor model 2N7002 and an 18-bit ADC model AD4003. This assembly was then subjected to simulation using the LTSPICE software, applying actual seismic data acquired from geophones during a live seismic exploration. Given that the conventional sampling frequency for this application is approximately 2 kHz, it is required that the stochastic Magnetic Tunnel Junction's (sMTJ's) retention time, denoted as (τ), does not exceed 500 microseconds.

The simulation outcomes presented in FIG. 8 illustrate the response of the p-bit (V_{CLK}) when stimulated by an input signal from an active seismic geophone sensor. These results confirm the p-bit's capacity for real-time probabilistic detection of seismic events. Additionally, the findings indicate that the reference voltage (V_{REF}) can be adjusted to calibrate the average minimum random sampling rate (X) during intervals when no seismic activity is detected.

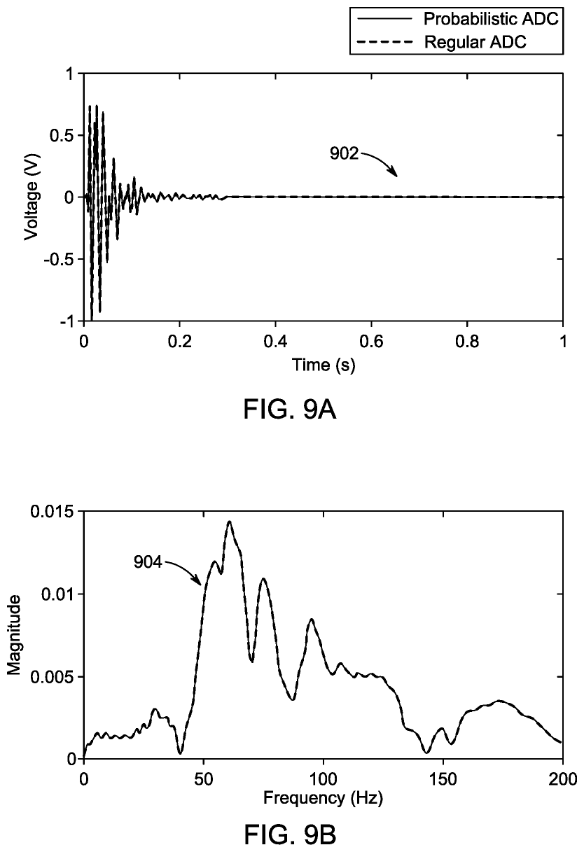

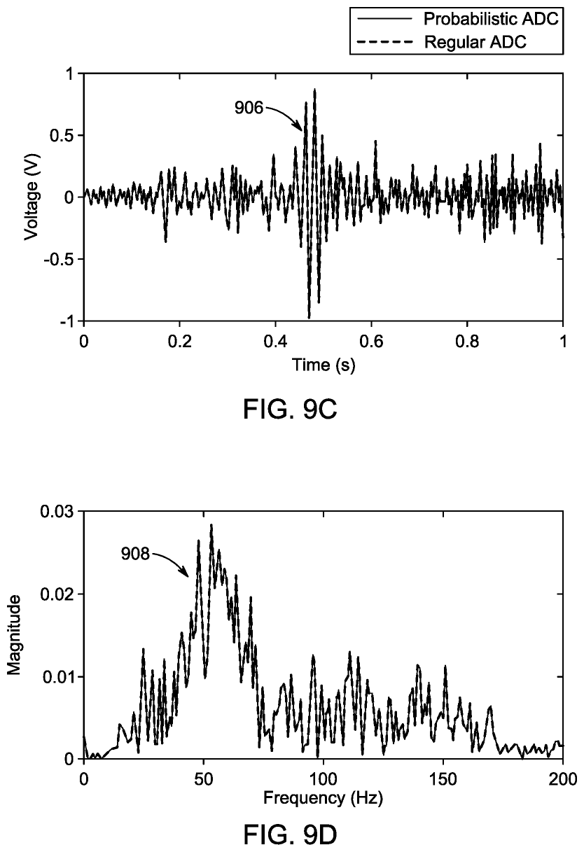

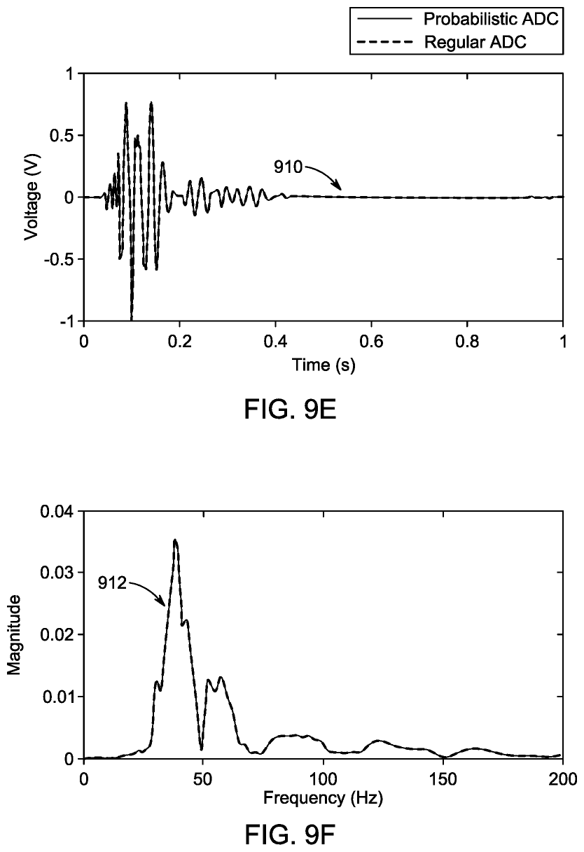

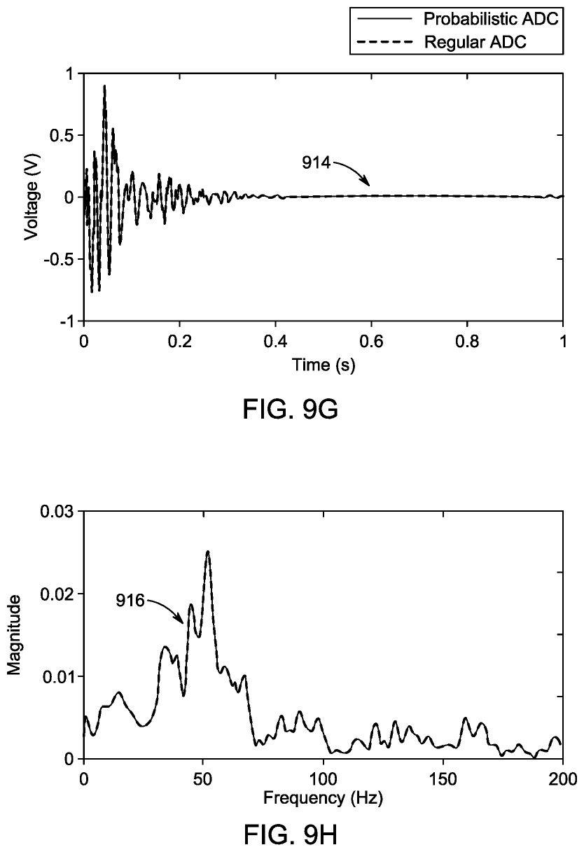

FIG. 9A-FIG. 9H depict comparison between regular sampling (Regular ADC) and probabilistic autonomous sampling (Probabilistic ADC) based on simulation results on four active seismic event signals, in accordance with the present embodiment. The sampling frequency for the regular ADC is 2 kHz.

FIG. 9A illustrates transient plots of the reconstructed sensor signals for a seismic activity 1, in accordance with one embodiment. Curve 902-1 depicts value of a probabilistic ADC, and curve 902-2 depicts value of a regular ADC.

FIG. 9B illustrates corresponding frequency spectra for the sensor signals for a seismic activity 1, in accordance with one embodiment. Curve 904-1 depicts value of a probabilistic ADC, and curve 904-2 depicts value of a regular ADC.

FIG. 9C illustrates transient plots of the reconstructed sensor signals for a seismic activity 2, in accordance with one embodiment. Curve 906-1 depicts value of a probabilistic ADC, and curve 906-2 depicts value of a regular ADC.

FIG. 9D illustrates corresponding frequency spectra for the sensor signals for a seismic activity 2, in accordance with one embodiment. Curve 908-1 depicts value of a probabilistic ADC, and curve 908-2 depicts value of a regular ADC.

FIG. 9E illustrates transient plots of the reconstructed sensor signals for a seismic activity 3, in accordance with one embodiment. Curve 910-1 depicts value of a probabilistic ADC, and curve 910-2 depicts value of a regular ADC.

FIG. 9F illustrates corresponding frequency spectra for the sensor signals for a seismic activity 3, in accordance with one embodiment. Curve 912-1 depicts value of a probabilistic ADC, and curve 912-2 depicts value of a regular ADC.

FIG. 9G illustrates transient plots of the reconstructed sensor signals for a seismic activity 4, in accordance with one embodiment. Curve 914-1 depicts value of a probabilistic ADC, and curve 914-2 depicts value of a regular ADC.

FIG. 9H illustrates corresponding frequency spectra for the sensor signals for a seismic activity 4, in accordance with one embodiment. Curve 916-1 depicts value of a probabilistic ADC, and curve 916-2 depicts value of a regular ADC.

The fidelity of the data procured through the innovated probabilistic sensing system was assessed by comparing it with data from a standard ADC functioning in a continuous sampling mode. The signal reconstruction for four discrete seismic occurrences, derived from the active survey and processed using both methodologies, was executed with linear interpolation amongst sampled points. These reconstructions are exhibited in FIG. 9, with representations in both temporal and spectral domains. The comparative analysis corroborated that the reconstructed outputs in the time and frequency spectrums are congruent, as illustrated by FIG. 9A-FIG. 9H. The two sampling schemes were quantitatively evaluated based on the normalized mean squared error (NMSE), described by eq. (2):

$$NMSE = \frac{{‖ ( {Y}_{s e n s o r} - {Y}_{s c h e m e} ) ‖}_{2}^{2}}{{‖ ( {Y}_{s e n s o r} ) ‖}_{2}^{2}} \qquad ( 2 )$$

Where ∥ ∥₂² is the 2^{nd} norm of the vector, while Yₛₑₙₛₒᵣ and Y_{scheme} represent the vectors of the raw seismic data and the reconstructed data, using the sampling scheme, respectively. Table I compares the NMSE of all signals reconstructed using both schemes in time and frequency domains. For all evaluated NMSEs, the differences between both schemes are non-distinguishable. The NMSE in the 0-200 Hz frequency range (application critical range) indicates that the error using the proposed sensing approach can be as small as 0.007%. Most importantly, Table 1 further demonstrates that probabilistic autonomous sensing can achieve accurate data acquisition at a much lower number of samples than regular ADCs. In the four events investigated, a 47.56% saving in the number of samples and in the active operation time of the ADC were achieved.

TABLE I
Quantitative Comparison Between Sampling Schemes

| | | | | Saving in |
|---|---|---|---|---|
| | Normalized Mean Squared Error | | | Samples & |
| Sampling | Time | Freq.* | Freq.** | Operation |
| Scheme | Domain | Domain | Domain | Time |
| Continuous | 1.46 × 10⁻² | 1.55 × 10⁻⁴ | 2.33 × 10⁻⁵ | 0% |
| (Regular) | | | | |
| Probabilistic | 1.54 × 10⁻² | 2.15 × 10⁻⁴ | 6.76 × 10⁻⁵ | 47.56% |
| Autonomous | | | | |

*Up to 2 kHz,
**Up to 200 Hz

Numerous modifications and variations of the present disclosure are possible in light of the above teachings. It is therefore to be understood that within the scope of the appended claims, the invention may be practiced otherwise than as specifically described herein.

1. A method for acquiring data in a probabilistic manner in an event-based data acquisition system, the method comprising:
obtaining an analog sensor signal from a sensor;
extracting, using a feature extraction unit, features from the analog sensor signal, wherein the features are indicative of a presence or an absence of an event of interest;
generating, by an activation unit comprising a magnetic tunnel junction (MTJ)-based p-bit, based on the features, an output signal for use in triggering acquisition of event data from the analog sensor signal in a probabilistic manner, wherein the generating includes:
configuring the p-bit to a first value for a period of time the features indicate a presence of the event of interest to cause acquisition of the event data,
configuring the p-bit to a second value for a period of time the features indicate an absence of the event of interest to prevent acquisition of the event data,
configuring an amount of time, the p-bit is configured to the first value to cause acquisition of the event data randomly in a period of time wherein the features are not definitive enough to indicate an absence or a presence of the event of interest, and
outputting the output signal with a value of the p-bit; and
acquiring, by a sampling unit, the event data based on the output signal.

2. The method of claim 1, wherein acquiring the event data based on the output signal includes:
acquiring the event data from the analog sensor signal for the period of time the output signal has the first value.

3. The method of claim 1, wherein acquiring the event data based on the output signal includes:
adjusting average random data acquisition rate to a specified rate for a period of time when the features indicate an absence of the event of interest.

4. The method of claim 3, wherein adjusting the average random data acquisition rate includes:
configuring the p-bit to the first value for a portion of the period of time when the features indicate an absence of the event of interest.

5. The method of claim 3, wherein the average random data acquisition rate is adjusted by adjusting a voltage applied to a gate of a transistor of the activation unit to which the MTJ is connected.

6. The method of claim 5, wherein adjusting the voltage includes increasing the voltage to increase the average random data acquisition rate.

7. The method of claim 1, wherein acquiring the event data based on the output signal includes:
adjusting average random data acquisition rate to a first rate that is between a second rate and a third rate for a period of time when the features are not definitive enough to indicate an absence or presence of the event of interest, wherein the second rate is the average random data acquisition rate corresponding to a period of time when the features indicate a presence of the event of interest and the third rate is the average random data acquisition rate corresponding to a period of time when the features indicate an absence of the event of interest.

8. The method of claim 1, wherein generating the output signal includes:
providing an output voltage from the feature extraction unit as a first input voltage to a comparator of the activation unit, wherein the output voltage is indicative of the features; and
providing a voltage from a drain of a transistor to which the MTJ is connected as a second input voltage to the comparator, wherein the comparator determines a value of the p-bit based on the first input voltage and the second input voltage.

9. The method of claim 1 further comprising:
performing a logical AND operation between the output signal and a synchronous clock signal to generate an output clock signal.

10. The method of claim 9, wherein acquiring the event data includes:
acquiring the event data based on the output clock signal.

11. A method for acquiring data in a probabilistic manner in an event-based data acquisition system, the method comprising:
extracting, using a feature extraction unit, features from an analog sensor signal, wherein the features are indicative of a presence or an absence of an event of interest;
generating, by an activation unit comprising a magnetic tunnel junction (MTJ)-based p-bit, an output signal indicative of an output of the p-bit based on the features, wherein the output includes a first value or a second value of the p-bit for different periods of time, and wherein the first value is indicative of a presence of the event of interest in the features and the second value is indicative of an absence of the event of interest in the features; and
acquiring, by a sampling unit, the event data from the analog sensor signal for the period of time the output signal has the first value.

12. The method of claim 11, wherein generating the output signal includes:
providing an output voltage from the feature extraction unit as a first input voltage to a comparator of the activation unit, wherein the output voltage is indicative of the features; and
providing a voltage from a drain of a transistor to which the MTJ is connected as a second input voltage to the comparator, wherein the comparator determines the output signal based on the first input voltage and the second input voltage.

13. The method of claim 11, wherein generating the output signal includes:
configuring the p-bit to the first value for a period of time the features indicate a presence of the event of interest to cause acquisition of the event data,
configuring the p-bit to the second value for a period of time the features indicate an absence of the event of interest to prevent acquisition of the event data,
configuring an amount of time the p-bit is configured to the first value to cause acquisition of the event data randomly in a period of time wherein the features are not definitive enough to indicate an absence or a presence of the event of interest, and
outputting the output signal with a value of the p-bit.

14. The method of claim 11, wherein acquiring the event data based on the output signal includes:
adjusting average random data acquisition rate to a non-zero rate for a period of time when the features indicate an absence of the event of interest.

15. The method of claim 14, wherein adjusting the average random data acquisition rate includes:
configuring the p-bit to the first value for a portion of the period of time when the features indicate an absence of the event of interest.

16. The method of claim 14, wherein the average random data acquisition rate is adjusted by adjusting a voltage applied to a gate of a transistor of the activation unit to which the MTJ is connected.

17. The method of claim 11, wherein acquiring the event data based on the output signal includes:
adjusting average random data acquisition rate to a first rate that is between a second rate and a third rate for a period of time when the features are not definitive enough to indicate an absence or presence of the event of interest, wherein the second rate is the average random data acquisition rate corresponding to a period of time when the features indicate a presence of the event of interest and the third rate is the average random data acquisition rate corresponding to a period of time when the features indicate an absence of the event of interest.

18. A an event-based data acquisition system for acquiring data in a probabilistic manner, the method comprising:
a feature extraction unit configured to extract features from an analog sensor signal, wherein the features are indicative of a presence or an absence of an event of interest in the analog sensor signal;
an activation unit comprising a magnetic tunnel junction (MTJ)-based p-bit, wherein the activation unit is configured to generate an output signal based on the features, wherein the output signal is indicative of an output of the p-bit, the output including a first value or a second value of the p-bit for different periods of time, and wherein the first value is indicative of a presence of the event of interest in the features and the second value is indicative of an absence of the event of interest in the features; and
a sampling unit to acquire the event data from the analog sensor signal for the period of time the output signal has the first value.

19. The system of claim 18, wherein the activation unit is configured to:
receive an output voltage from the feature extraction unit as a first input voltage, wherein the output voltage is indicative of the features; and
determine a value of the p-bit based on the first input voltage and a second input voltage at a drain of a transistor to which the MTJ is connected.

20. The system of claim 18, wherein the activation unit is configured to adjust average random data acquisition rate of the sampling unit for a period of time when the features indicate an absence of the event of interest based on a voltage applied to a gate of a transistor to which the MTJ is connected.
